(19) United States
(12) Patent Application Publication
(10) Pub. No.: US 2016/0043218 A1
(43) Pub. Date: Feb. 11, 2016

(54) SEMICONDUCTOR COMPONENT AND METHOD OF MANUFACTURE

(71) Applicant: Semiconductor Components Industries, LLC, Phoenix, AZ (US)

(72) Inventors: Peter Moens, Zottegem (BE); Chun-Li Liu, Scottsdale, AZ (US)

(21) Appl. No.: 14/452,191

(22) Filed: Aug. 5, 2014

(51) Int. Cl. H01L 29/78; H01L 29/06; H01L 21/02; H01L 29/66; H01L 21/285; H01L 29/417; H01L 21/768; H01L 29/20; H01L 21/762

(52) U.S. Cl. CPC H01L 29/7827; H01L 29/2003; H01L 29/0649; H01L 21/0254; H01L 21/76224; H01L 21/0217; H01L 21/02178; H01L 21/28575; H01L 21/02532; H01L 21/02595; H01L 29/41741; H01L 29/41766; H01L 21/76898; H01L 29/66666

(57) ABSTRACT

In accordance with an embodiment, a method for manufacturing a semiconductor component includes forming a first trench through a plurality of layers of compound semiconductor material. An insulating material is formed on first and second sidewalls of the first trench and first and second sidewalls of the second trench and a trench fill material is formed in the first and second trenches. In accordance with another embodiment, the semiconductor component includes a plurality of layers of compound semiconductor material over a body of semiconductor material and first and second filled trenches extending into the plurality of layers of compound semiconductor material. The first trench has first and second sidewalls and a floor and a first dielectric liner over the first and second sidewalls and the second trench has first and second sidewalls and a floor and second dielectric liner over the first and second sidewalls of the second trench.

### TECHNICAL FIELD

The present invention relates, in general, to electronics and, more particularly, to semiconductor structures thereof, and methods of forming semiconductor devices.

### BACKGROUND

In the past, the semiconductor industry used various different device structures and methods to form semiconductor devices such as, for example, diodes, Schottky diodes, Field Effect Transistors (FETs), High Electron Mobility Transistors (HEMTs), etc. Devices such as diodes, Schottky diodes, and FETs were typically manufactured from a silicon substrate. Drawbacks with silicon based semiconductor devices include low breakdown voltages, excessive reverse leakage current, large forward voltage drops, unsuitably low switching characteristics, high power densities, and high costs of manufacture. To overcome these drawbacks, semiconductor manufacturers have turned to manufacturing semiconductor devices from compound semiconductor substrates such as, for example, III-N semiconductor substrates, III-V semiconductor substrates, II-VI semiconductor substrates, etc. Although these substrates have improved device performance, they are fragile and add to manufacturing costs.

Typically, compound semiconductor substrates are comprised of a plurality of layers of semiconductor material. For example, a compound semiconductor substrate may include a substrate layer, a nucleation layer, a buffer layer, a channel layer, and a strained layer. A drawback with these structures is that donors at the interfaces between the layers increase the leakage current by orders of magnitude. In embodiments in which the substrate layer is silicon, an inversion channel at the interface of the silicon and the nucleation layer causes leakage to the sidewalls of the semiconductor die. A III-N compound semiconductor material that includes an isolation implant to reduce leakage currents caused by metal contacting the peripheral edges of a semiconductor die has been described in U.S. Patent Application Publication Number 2013/0099324 A1 by Jenn Hwa Huang et al. and published on Apr. 25, 2013.

Accordingly, it would be advantageous to have a structure and method for manufacturing a semiconductor component to inhibit leakage currents and to improve the performance and manufacturability of semiconductor components manufactured from compound semiconductor substrates. It would be of further advantage for the structure and method to be cost efficient to implement.

### BRIEF DESCRIPTION OF THE DRAWINGS

The present invention will be better understood from a reading of the following detailed description, taken in conjunction with the accompanying drawing figures, in which like reference characters designate like elements and in which:

FIG. 1 is a cross-sectional view of a semiconductor component during manufacture in accordance with an embodiment of the present invention;

FIG. 2 is a cross-sectional view of the semiconductor component of FIG. 1 at a later stage of manufacture;

FIG. 3 is a cross-sectional view of the semiconductor component of FIG. 2 at a later stage of manufacture;

FIG. 4 is a cross-sectional view of the semiconductor component of FIG. 3 at a later stage of manufacture;

FIG. 5 is a cross-sectional view of the semiconductor component of FIG. 4 at a later stage of manufacture;

FIG. 6 is a cross-sectional view of the semiconductor component of FIG. 2 at a later stage of manufacture;

FIG. 7 is a cross-sectional view of the semiconductor component of FIG. 6 at a later stage of manufacture;

FIG. 8 is a cross-sectional view of the semiconductor component of FIG. 7 at a later stage of manufacture;

FIG. 9 is a cross-sectional view of the semiconductor component of FIG. 8 at a later stage of manufacture;

FIG. 10 is a cross-sectional view of the semiconductor component of FIG. 9 at a later stage of manufacture;

FIG. 11 is a cross-sectional view of a semiconductor component during manufacture in accordance with another embodiment of the present invention;

FIG. 12 is a cross-sectional view of the semiconductor component of FIG. 11 at a later stage of manufacture; and

FIG. 13 is a cross-sectional view of the semiconductor component of FIG. 12 at a later stage of manufacture.

For simplicity and clarity of illustration, elements in the figures are not necessarily to scale, and the same reference characters in different figures denote the same elements. Additionally, descriptions and details of well-known steps and elements are omitted for simplicity of the description. As used herein current carrying electrode means an element of a device that carries current through the device such as a source or a drain of an MOS transistor or an emitter or a collector of a bipolar transistor or a cathode or anode of a diode, and a control electrode means an element of the device that controls current flow through the device such as a gate of an MOS transistor or a base of a bipolar transistor. Although the devices are explained herein as certain n-channel or p-channel devices, or certain n-type or p-type doped regions, a person of ordinary skill in the art will appreciate that complementary devices are also possible in accordance with embodiments of the present invention. It will be appreciated by those skilled in the art that the words during, while, and when as used herein are not exact terms that mean an action takes place instantly upon an initiating action but that there may be some small but reasonable delay, such as a propagation delay, between the reaction that is initiated by the initial action. The use of the words approximately, about, or substantially means that a value of an element has a parameter that is expected to be very close to a stated value or position. However, as is well known in the art there are always minor variances that prevent the values or positions from being exactly as stated. It is well established in the art that variances of up to about ten per cent (10%) (and up to twenty per cent (20%) for semiconductor doping concentrations) are regarded as reasonable variances from the ideal goal of exactly as described.

### DETAILED DESCRIPTION

Generally, the present invention provides a semiconductor component and a method for manufacturing the semiconductor component wherein the semiconductor component comprises trench based isolation structures. In accordance with an embodiment, a body of semiconductor material having one or more semiconductor layers formed thereon is provided. A plurality of trenches is formed in the plurality of semiconductor layers, wherein each trench has a floor and opposing sidewalls. A layer of insulating material is formed on the opposing sidewalls of one or more of the plurality of trenches and a trench fill material is formed in the one or more trenches having the layer of insulating material on the opposing sidewalls.

In accordance with another embodiment, a method for manufacturing a semiconductor component is provided, wherein the method comprises providing a body of semiconductor material having a surface; forming a nucleation layer on the body of semiconductor material, form a layer of III-nitride material on the nucleation layer; forming a plurality of trenches, wherein each trench extends through the layer of III-nitride material, the nucleation layer, and into the body of semiconductor material, and wherein each trench has a floor and opposing sidewalls; forming a layer of insulating material on the opposing sidewalls of the first trench of the plurality of trenches and on the opposing sidewalls of a second trench of the plurality of trenches; and forming a trench fill material in the first and second trenches.

In accordance with another embodiment, the method includes forming a layer of insulating material on the opposing sidewalls of the first and second trenches wherein the insulating material is selected from the group of insulating material comprising aluminum nitride and silicon nitride.

In accordance with another embodiment, the method includes forming an electrically conductive material in the first trench and in the second trench.

In accordance with another embodiment, the method includes forming a trench fill material in the first and second trenches wherein the trench fill material is doped polysilicon that contacts a body of semiconductor material.

In accordance with another embodiment, the method includes forming a trench fill material in the first and second trenches wherein the trench fill material is an electrically insulating material.

In accordance with another embodiment, the method includes forming a layer of insulating material on the floors of the first and second trenches.

In accordance with another embodiment, the method includes forming an insulating material selected from the group of insulating material comprising aluminum nitride and silicon nitride on the floor and on the opposing sidewalls of first and second trenches.

In accordance with another embodiment, the method includes providing a body of semiconductor material having a surface wherein the body of semiconductor material is selected from the group of semiconductor materials comprising silicon, silicon nitride, gallium nitride, and sapphire.

In accordance with another embodiment, the method includes forming a control electrode and first and second current carrying electrodes over the strained layer.

In accordance with another embodiment, a method for manufacturing a semiconductor component is provided wherein the method comprises providing a body of semiconductor material; forming a plurality of layers of a compound semiconductor material on the body of semiconductor material; forming a first trench through the plurality of layers of the compound semiconductor material, the first trench having first and second sidewalls and floor; forming a second trench through the plurality of layers of compound semiconductor material, the second trench having first and second sidewalls and a floor; forming an electrically insulating material on the first and second sidewalls of the first trench and on the first and second sidewalls of the second trench; forming a trench fill material in the first and second trenches; and forming a control electrode and first and second current carrying electrodes over the plurality of layer of compound semiconductor material that are between the first and second trenches.

In accordance with another embodiment, wherein forming the plurality of layers of compound semiconductor material includes: forming a layer of aluminum nitride on the body of semiconductor material; forming a layer of III-N material on the layer of aluminum nitride; forming a gallium nitride layer on the layer of III-N material; and forming a layer of aluminum gallium nitride on the gallium nitride layer.

In accordance with another embodiment, the method includes forming a layer of III-N material from gallium nitride.

In accordance with another embodiment, the method includes forming a trench fill material in the first and second trenches that includes forming one of doped polysilicon or oxide in the first and second trenches.

In accordance with another embodiment, the method includes forming the insulating material on the first and second sidewalls of the first trench and on the first and second sidewalls of the second trench wherein the insulating material is formed on the floor of the second trench.

In accordance with another embodiment, the method includes forming trench fill material in the first and second trenches by forming doped polysilicon in the first and second trenches, wherein the doped polysilicon in the first trench contacts the body of semiconductor material.

In accordance with another embodiment, the method includes electrically coupling one of the first current carrying electrode or the second current carrying electrode to the trench fill material in the first trench.

In accordance with another embodiment, a semiconductor component comprises a body of semiconductor material; a plurality of layers of compound semiconductor material over the body of semiconductor material; first and second filled trenches extending into the plurality of layers of compound semiconductor material, wherein the first trench includes first and second sidewalls and a floor and a first dielectric liner over the first and second sidewalls and wherein the second trench includes first and second sidewalls and a floor and second dielectric liner over the first and second sidewalls of the second trench; and a source electrode, a drain electrode, and a gate electrode over the plurality of layers of compound semiconductor material.

In accordance with another embodiment, the second dielectric liner is over the floor of the second trench and wherein the trench fill material comprises polysilicon, wherein the polysilicon contacts the body of semiconductor material.

In accordance with another embodiment, an electrical interconnect connects one of the source electrode or the drain electrode to the trench fill material in the first trench.

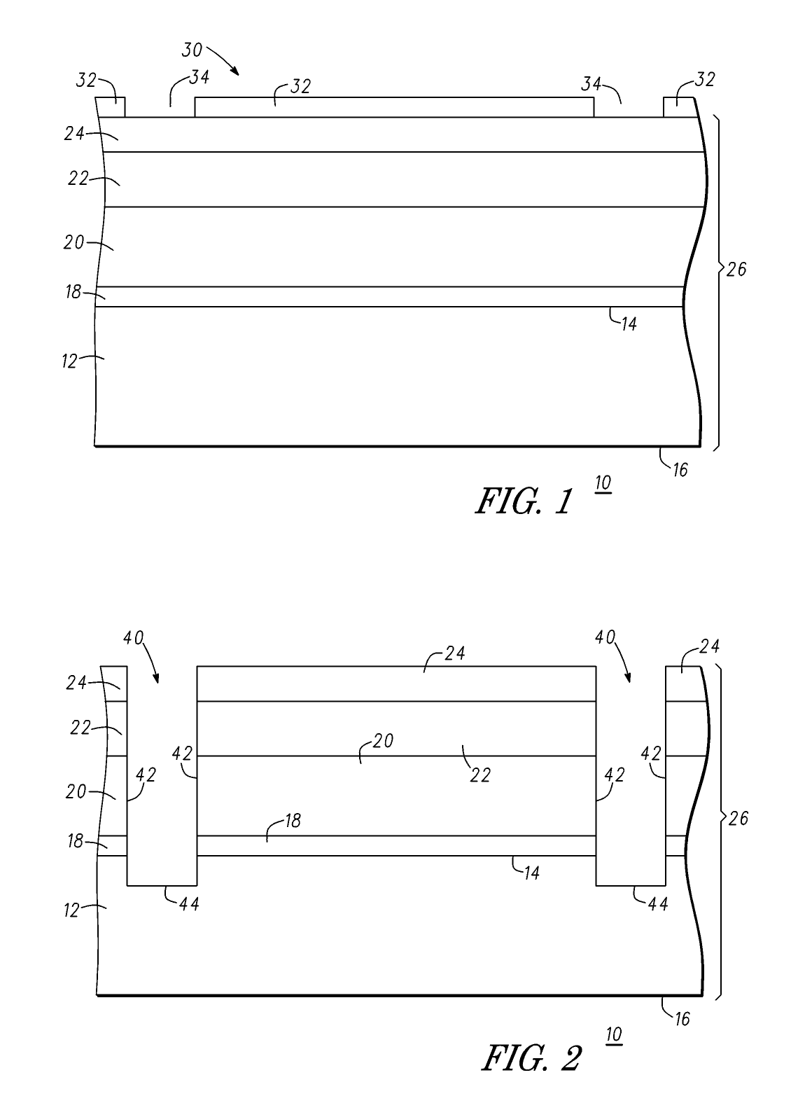

FIG. 1 is a cross-sectional view of a portion of a semiconductor component 10 such as, for example, a Light Emitting Diode (LED), a power switching device, a regulator, a protection circuit, a driver circuit, etc. during manufacture in accordance with an embodiment of the present invention. What is shown in FIG. 1 is a semiconductor substrate 12 having opposing surfaces 14 and 16. Surface 14 may be referred to as a front or top surface and surface 16 may be referred to as a bottom or back surface. Semiconductor substrate 12 may be of p-type conductivity, n-type conductivity, or it may be an intrinsic semiconductor material and may be referred to as a body of semiconductor material. In accordance with an embodiment, semiconductor substrate 12 is silicon doped with an impurity material of p-type conductivity and has a resistivity ranging from about 1×10⁻³ Ohm-centimeters (a-cm) to about 100 Ω-cm. Alternatively, substrate 12 can be silicon, silicon carbide, sapphire, a compound semiconductor material such as, for example, gallium nitride, gallium arsenide, indium phosphide, or the like.

In accordance with an embodiment, substrate 12 is placed in a reaction chamber and a nucleation layer 18 having a thickness ranging from about a mono-layer of carbon to about 100 μm is formed on silicon substrate 12. Nucleation layer 18 can be formed using Molecular Beam Epitaxy (MBE), Physical Vapor Deposition (PVD), or using chemical vapor deposition techniques such as, for example, a Metalorganic Chemical Vapor Deposition (MOCVD) technique, a Plasma-enhanced Chemical Vapor Deposition (PECVD) technique, a Low Pressure Chemical Vapor Deposition (LPCVD) technique, or the like. By way of example, nucleation layer 18 is aluminum nitride. Other suitable materials for nucleation layer 18 include silicon and aluminum nitride, silicon carbide, aluminum gallium nitride, or the like.

A buffer layer 20 having a thickness ranging from about 0.1 μm to about 100 μm is formed on nucleation layer 18 at a temperature ranging from about 150 degrees Celsius (° C.) to about 1,500° C. In accordance with an embodiment, buffer layer 20 is a layer of III-nitride material, which may be referred to as a III-N material. Suitable materials for buffer layer 20 include Group III-N materials such as, for example, aluminum nitride (AlN), gallium nitride (GaN), indium nitride (InN), aluminum gallium nitride (AlGaN), aluminum indium nitride (AlInN), aluminum indium gallium nitride (AlInGaN), indium gallium nitride (InGaN), or the like. Buffer layer 20 may be formed using MBE, PECVD, MOCVD, Metal Organic Vapor Phase Epitaxy (MOVPE), Remote Plasma Enhanced Chemical Vapor Deposition (RP-CVD), hydride vapor phase epitaxy (HVPE), Liquid Phase Epitaxy (LPE), Chloride Vapor Phase Epitaxy (Cl-VPE), or the like. It should be noted that buffer layer 20 may be comprised of a plurality of layers such as for example a plurality of MN layers, a plurality of GaN layers, or alternating stacked MN and GaN layers. Buffer layer 20 may be of p-type conductivity, n-type conductivity, or it may be an intrinsic semiconductor material.

Still referring to FIG. 1, a channel layer 22 having a thickness ranging from about 0.1 μm to about 10 μm is formed on buffer layer 20 using one or more techniques selected from the group of techniques including MBE, PECVD, MOCVD, MOVPE, RP-CVD, HVPE, LPE, Cl-VPE, or the like. By way of example, channel layer 22 is a GaN layer having a thickness ranging from about 0.1 μm to about 1 μm.

A strained layer 24 having a thickness ranging from about 10 nanometers (nm) to about 1,000 nm is formed on channel layer 22 using one or more techniques selected from the group of techniques including MBE, PECVD, MOCVD, MOVPE, RP-CVD, HVPE, LPE, Cl-VPE, or the like. By way of example, strained layer 24 is an AlGaN layer having a thickness ranging from about 1 nm to about 30 nm. Substrate 12, nucleation layer 18, buffer layer 20, channel layer 22, and strained layer 24 may be referred to collectively as a semiconductor material 26.

A layer of photoresist is patterned over strained layer 24 to form a masking structure 30 having masking elements 32 and openings 34 that expose portions of strained layer 24.

Referring now to FIG. 2, trenches 40 having sidewalls 42 and floors 44 are formed in the portions of semiconductor material exposed by openings 34 using, for example, a dry etching technique. It should be noted that sidewalls 42 that are on opposite sides of the same trench may be referred to as opposing sidewalls. In accordance with an embodiment, trenches 40 extend through strained layer 24, channel layer 22, buffer layer 20, nucleation layer 18, and into substrate 12, i.e., into the body of semiconductor material.

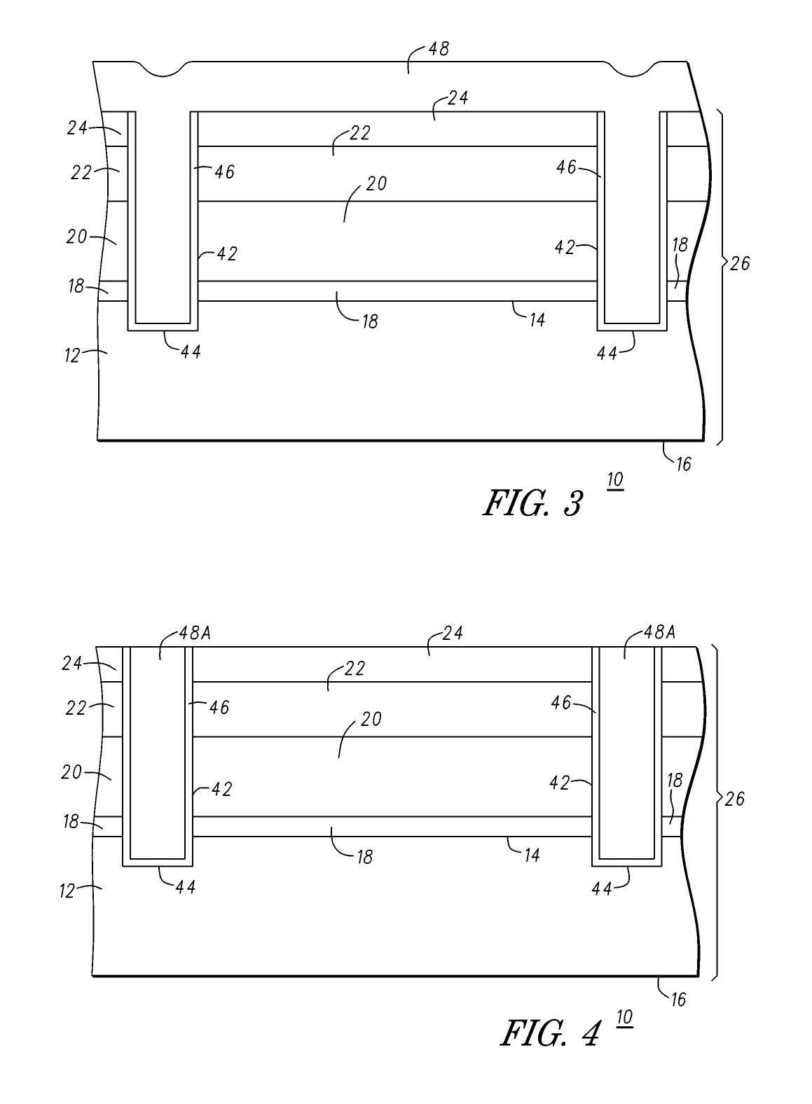

Referring now to FIG. 3, layers 46 of electrically insulating material are formed on sidewalls 42 and floors 44 of trenches 40. Layers 46 may be referred to as dielectric layers or dielectric liners. Layers 46 may be aluminum oxide, silicon nitride, or the like and may be formed by depositing a conformal layer of electrically insulating material and planarizing the conformal layer of electrically insulating material. A material 48 is formed on insulating layers 46, wherein material 48 fills trenches 40 and is formed on strained layer 24. Material 48 may be referred to as a trench fill material. In accordance with an embodiment, material 48 is an electrically conductive material such as, for example, polysilicon doped with an impurity material of the same conductivity type as substrate 12. Alternatively material 48 may be a metal, an insulating material, intrinsic polysilicon, or the like.

Referring now to FIG. 4, material 48 is planarized leaving portions 48A in trenches 40.

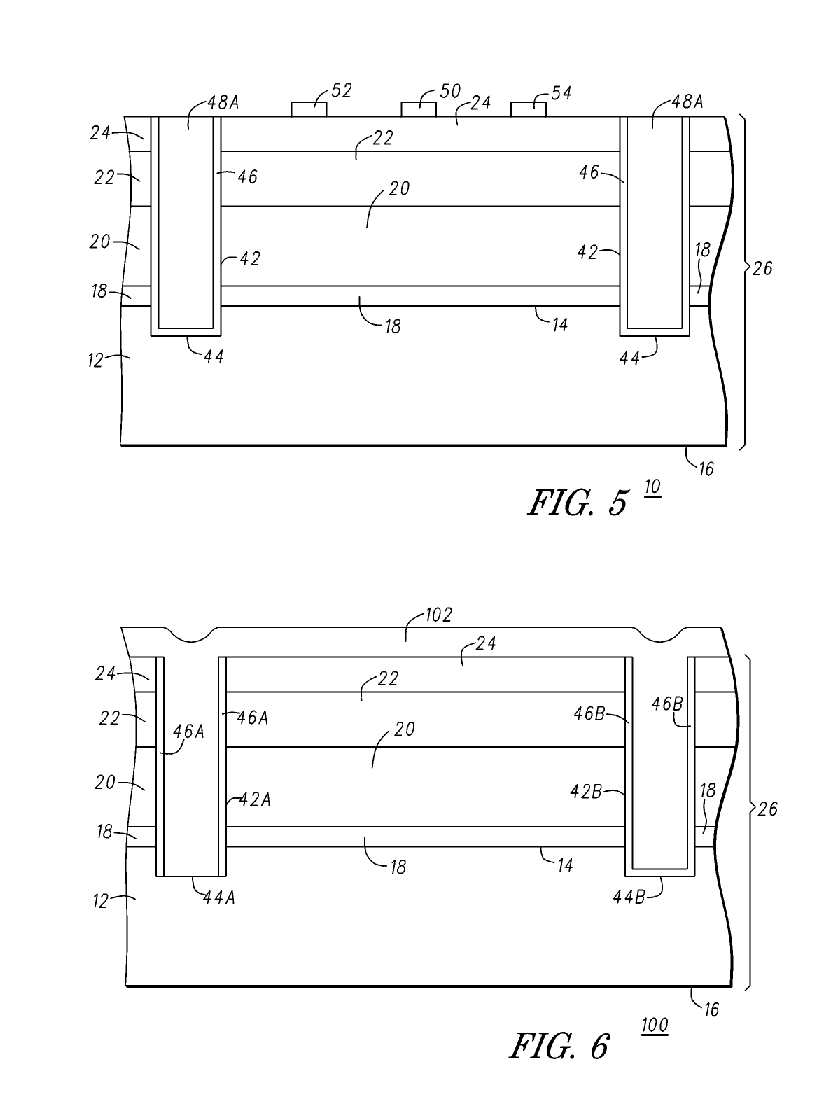

Referring now to FIG. 5, a control electrode such as, for example, a gate electrode 50, a current carrying electrode such as, for example, a source electrode 52, and a current carrying electrode such as, for example, a drain electrode 54 are formed on portions of strained layer 24 that are between trenches 40 that are filled with portions 48A of material 48. Thus, in accordance with an embodiment, semiconductor component 10 is a gallium nitride power device having trenches that are lined with an electrically insulating material. Lining the trenches with the electrically insulating material inhibits current leakage path formation along the gallium nitride/aluminum gallium nitride interfaces in the semiconductor material, which improves high voltage isolation.

Referring now to FIG. 6, a cross-sectional view of a semiconductor component 100 in accordance with another embodiment of the invention is shown, where the description of FIG. 6 continues from the description of FIG. 2. Reference character 10 of FIG. 2 has been replaced by reference character 100 in FIG. 6 to distinguish between the embodiments of FIGS. 2 and 6. In addition, reference characters A and B have been appended to reference character 40 to distinguish the trenches formed in semiconductor material 26 and reference characters A and B have been appended to reference characters 42 and 44 to distinguish the sidewalls and floor of trench 40A from the sidewall and floor of trench 40B, and reference characters A and B have been appended to reference character 46 to distinguish the dielectric material lining trenches 40A and 40B. What is shown in FIG. 6 are layers of electrically insulating material 46A formed on sidewalls 42A of trenches 40A and layer of electrically insulating material 46B formed on sidewalls 42B and floor 44B of trench 40B. Like layers 46, layers 46A and 46B may be referred to as dielectric layers or dielectric liners. Layers 46A and 46B may be aluminum oxide, silicon nitride, or the like and may be formed by depositing a conformal layer of electrically insulating material and etching the dielectric material using, for example, a reactive ion etch, wherein the etch is performed to expose floor 44A of trench 40A.

An electrically conductive material 102 is formed on insulating layers 46A and 46B and on floor 44B, wherein electrically conductive material 102 fills trenches 40, contacts floor 44A, and is formed on strained layer 24. In accordance with an embodiment, electrically conductive material 102 is polysilicon doped with an impurity material of the same conductivity type as substrate 12. Alternatively material 102 may be a metal or other electrically conductive material.

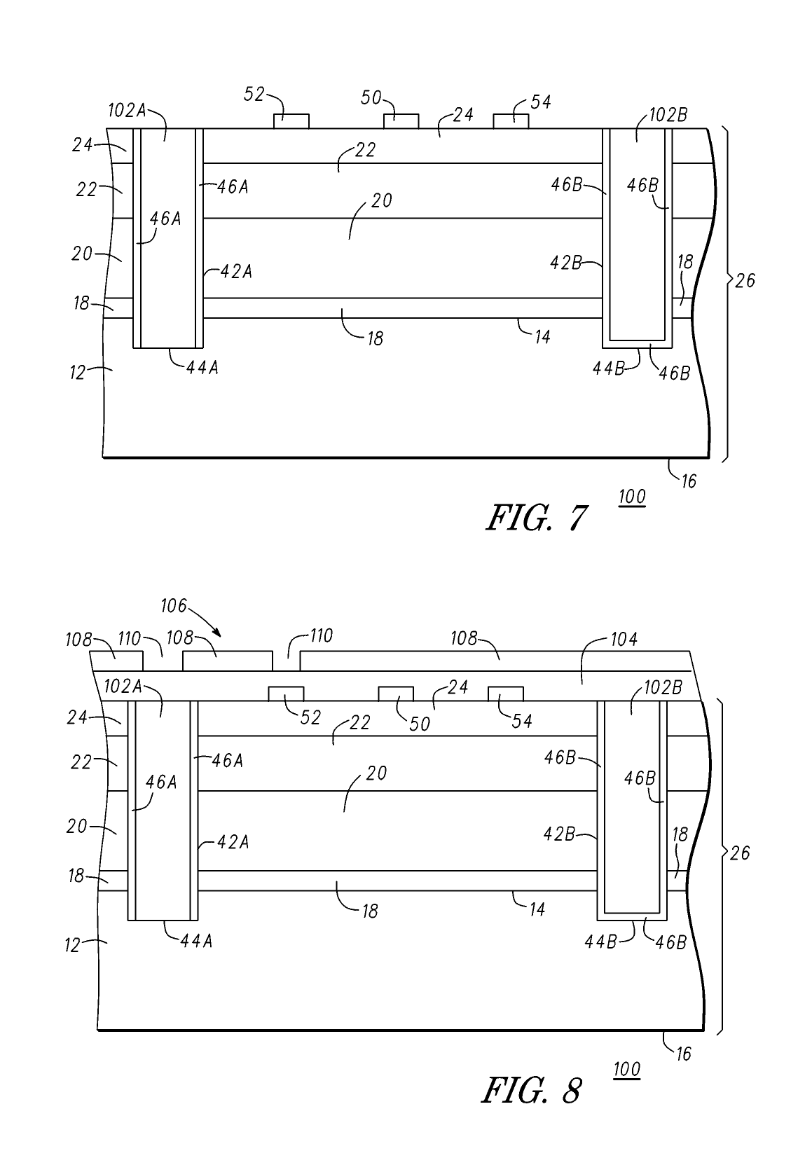

Referring now to FIG. 7, material 102 is planarized leaving portions 102A and 102B in the trenches 40. It should be noted that reference characters A and B have been appended to reference character 102 to distinguish between which electrode, i.e., a drain electrode or source electrode, may be coupled to the electrically conductive material filling trenches 40. A gate electrode 50, a source electrode 52, and a drain electrode 54 are formed on portions of strained layer 24 that are between trenches 40 that are filled with portions 102A and 102B of electrically conductive material 102.

Referring now to FIG. 8, a layer of dielectric material 104 is formed over strained layer 24, electrically conductive portions 102A and 102B, the exposed portions of insulating layers 46A and 46B, and over gate electrode 50, source electrode 52, and drain electrode 54. A layer of photoresist is patterned over dielectric layer 104 to form a masking structure 106 having masking elements 108 and openings 110 that expose portions of dielectric layer 104. Openings 110 expose portions of dielectric material 104 over source electrode 52 and electrically conductive material 102A.

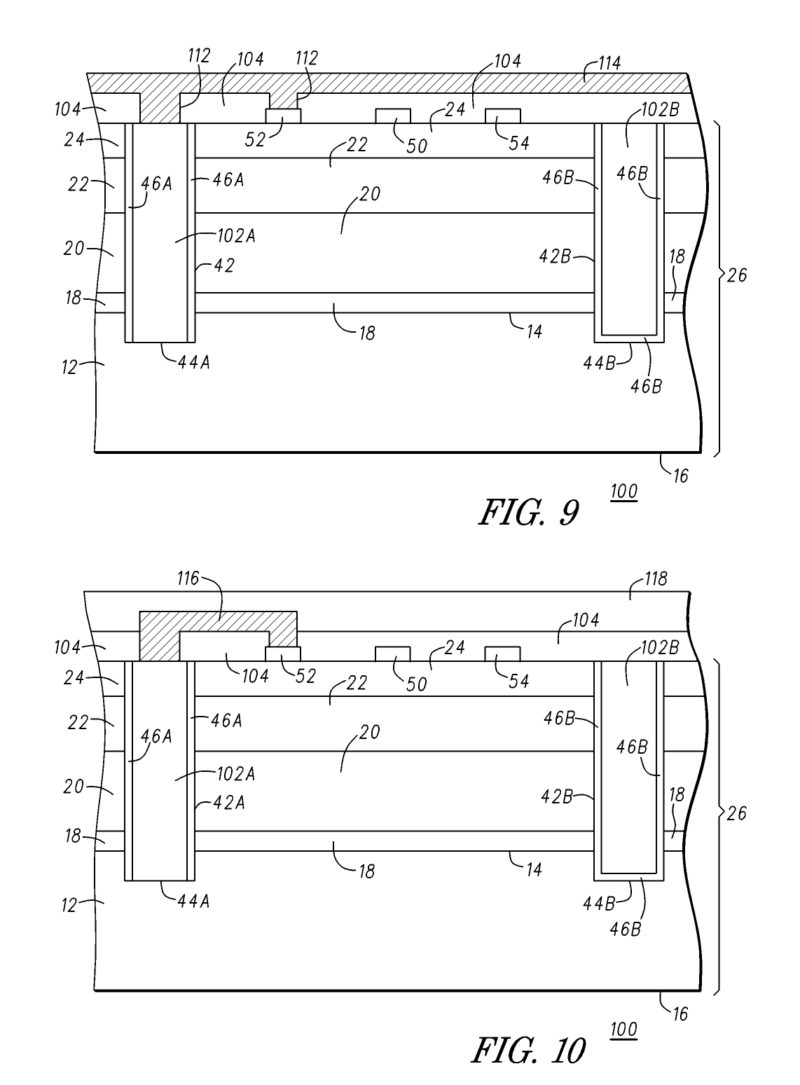

Referring now to FIG. 9, the portions of dielectric material 104 exposed by openings 110 are removed using, for example, a dry etch technique to form openings 112 that expose source electrode 52 and electrically conductive material 102A. An electrically conductive material 114 is formed on dielectric material 104 and in openings 112 to contact source electrode 52 and electrically conductive material 102A.

Referring now to FIG. 10, electrically conductive material 114 is removed from selected portions of dielectric layer 104 leaving an electrical interconnect 116 that connects source electrode 52 with electrically conductive material 102A, i.e., that connects source electrode 52 with trench fill material 102A. A passivation layer 118 is formed on dielectric layer 104 and electrical interconnect 116. By way of example, passivation layer 118 is a dielectric material such as, for example, oxide. Thus, in accordance with an embodiment, semiconductor component 100 is a gallium nitride power device having trenches with sidewalls that are lined with an electrically insulating material and wherein a floor of one of the trenches is lined with the electrically insulating material. Lining the sidewalls of the trenches and the floor of at least one of the trenches with the electrically insulating material inhibits current leakage path formation along the gallium nitride/aluminum gallium nitride interfaces in the semiconductor material, which improves high voltage isolation. Because dielectric material is absent from a floor of one of the trenches, the substrate of semiconductor component 100 electrically contacts its source. Thus, the source and the substrate can be coupled to a common potential such as, for example, ground.

Referring now to FIG. 11, a cross-sectional view of a semiconductor component 150 in accordance with another embodiment of the invention is shown, where the description of FIG. 11 continues from the description of FIG. 2. Reference character 10 of FIG. 2 has been replaced by reference character 150 in FIG. 11 to distinguish between the embodiments of FIGS. 2 and 11. In addition, reference characters A and B have been appended to reference character 40 to distinguish the trenches formed in semiconductor material 26 and reference characters A and B have been appended to reference characters 42 and 44 to distinguish the sidewalls and floor of trench 40A from the sidewalls and floor of trench 40B. Reference characters C and D have been appended to reference character 46 to distinguish the dielectric material lining trenches 40A and 40B. What is shown in FIG. 11 are layers of electrically insulating material 46C formed on sidewalls 42A and floor 44A of trench 40A and layer of electrically insulating material 46D formed on sidewalls 42B of trench 40B. Like layers 46, 46A, and 46B, layers 46C and 46D may be referred to as dielectric layers or dielectric liners. Layers 46C and 46D may be aluminum oxide, silicon nitride, or the like and may be formed by depositing a conformal layer of electrically insulating material and etching the dielectric material using, for example, a reactive ion etch, wherein is the etch is performed to expose floor 44B of trench 40B.

An electrically conductive material such as, for example, electrically conductive material 102 described with reference to FIG. 6 is formed on insulating layers 46A and 46B and on floor 44B, wherein electrically conductive material 102 fills trenches 40, contacts floor 44B, and is formed on strained layer 24.

A layer of dielectric material 104 formed over strained layer 24, electrically conductive portions 102A and 102B, the exposed portions of insulating layers 46C and 46D, and over gate electrode 50, source electrode 52, and drain electrode 54. A layer of photoresist is patterned over dielectric layer 104 to form a masking structure 151 having masking elements 152 and openings 154 that expose portions of dielectric layer 104. Openings 154 expose portions of dielectric material 104 over drain electrode 54 and electrically conductive material 102B.

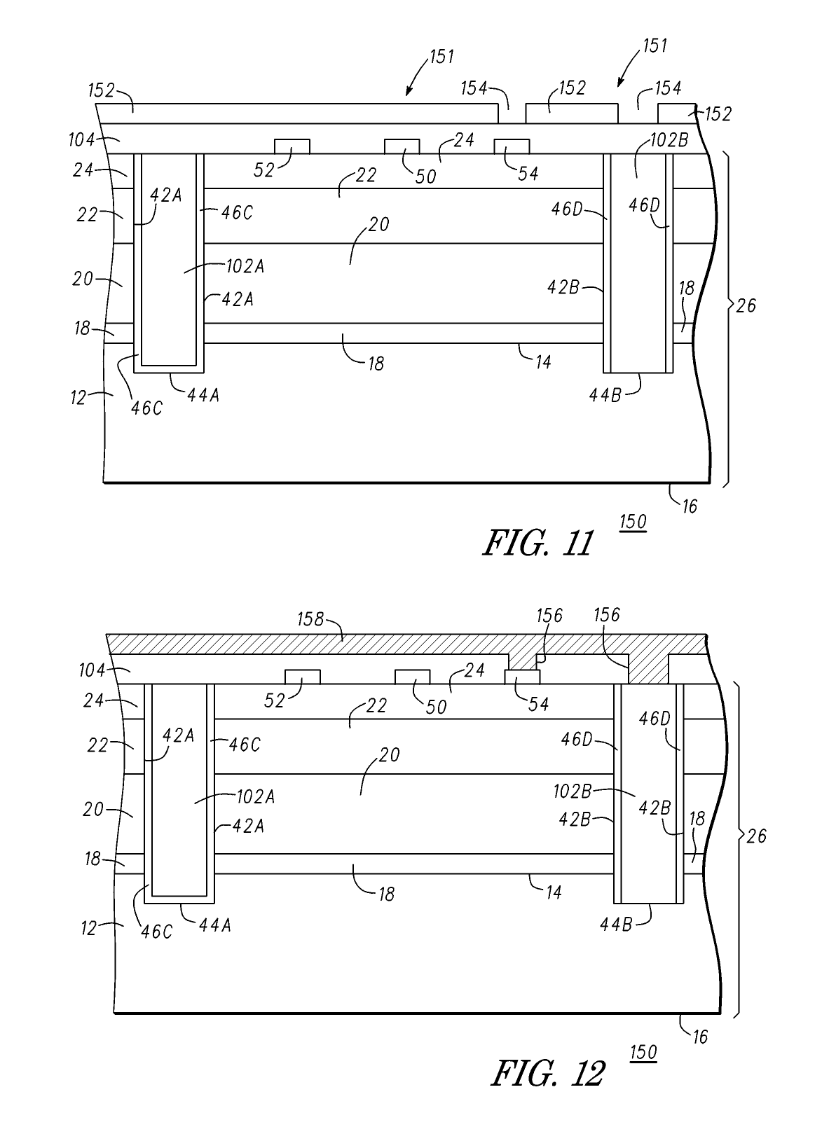

Referring now to FIG. 12, the portions of dielectric material 104 exposed by openings 154 are removed using, for example, a dry etch technique to form openings 156 that expose drain electrode 54 and electrically conductive material 102B. An electrically conductive material 158 is formed on dielectric material 104 and in openings 156 to contact drain electrode 54 and electrically conductive material 102B.

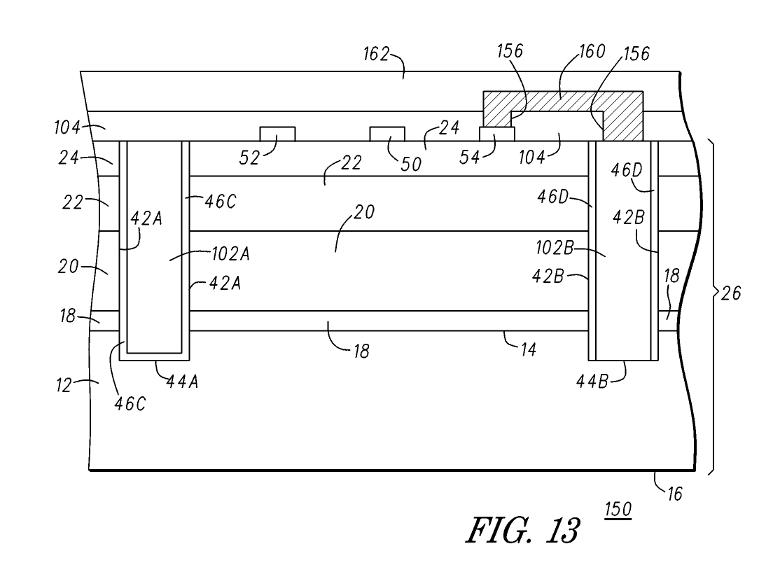

Referring now to FIG. 13, electrically conductive material 158 is removed from selected portions of dielectric layer 104 leaving an electrical interconnect 160 that connects drain electrode 54 with electrically conductive material 102B, i.e., that electrically connects the drain electrode with trench fill material 102B. A passivation layer 162 is formed on dielectric layer 104 and electrical interconnect 160. By way of example, passivation layer 162 is a dielectric material such as, for example, oxide. Thus, in accordance with an embodiment, semiconductor component 150 is a gallium nitride power device having trenches with sidewalls that are lined with an electrically insulating material and wherein a floor of one of the trenches is lined with the electrically insulating material. Lining the sidewalls of the trenches and the floor of at least one of the trenches with the electrically insulating material inhibits current leakage path formation along the gallium nitride/aluminum gallium nitride interfaces in the semiconductor material, which improves high voltage isolation. Because dielectric material is absent from a floor of one of the trenches, the substrate of semiconductor component 150 electrically contacts its drain. Thus, the drain and the substrate can be coupled to a common potential such as, for example, ground.

By now it should be appreciated that a semiconductor component and method for manufacturing the semiconductor component have been provided. In accordance with an embodiment, trenches are formed in a compound semiconductor heterostructure, wherein the trenches may be lined with an electrically insulating material and then filled with additional electrically insulating material or an electrically conductive material. By way of example, the compound semiconductor heterostructure is an aluminum-gallium-nitride/gallium-nitride (AlGaN/GaN) heterostructure. Lining the sidewalls and floors of the trenches inhibits leakage path formation along the gallium-nitride/aluminum-gallium-nitride interfaces in the bulk semiconductor material, which improves high voltage isolation. In accordance with another embodiment, a compound semiconductor device is configured so that dielectric material is absent from the floor of a trench containing an electrically conductive material that is electrically connected to a source of the compound semiconductor device. Thus, high voltage electrical isolation is improved and the source and the substrate of the compound semiconductor material can be coupled to the same electrical potential, for example ground. In accordance with another embodiment, a compound semiconductor device is configured so that dielectric material is absent from the floor of a trench containing an electrically conductive material that is electrically connected to a drain of the compound semiconductor device. Thus, high voltage electrical isolation is improved and the drain and the substrate of the compound semiconductor material can be coupled to the same electrical potential, for example ground.

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

1. A method for manufacturing a semiconductor component, comprising:
providing a body of semiconductor material having a surface;
forming a nucleation layer on the body of semiconductor material;
forming a layer of III-nitride material on the nucleation layer;
forming a plurality of trenches, wherein each trench extends through the layer of III-nitride material, the nucleation layer, and into the body of semiconductor material, and wherein each trench has a floor and opposing sidewalls;
forming a layer of insulating material on the opposing sidewalls of a first trench of the plurality of trenches, and on the opposing sidewalls of a second trench of the plurality of trenches, and on one of the floor of the first trench of the plurality of trenches or the floor of the second trench of the plurality of trenches, wherein insulating material is absent from the other of the floor of the first trench of the plurality of trenches or the second trench of the plurality of trenches; and
forming a trench fill material in the first and second trenches.

2. The method of claim 1, wherein forming the layer of insulating material on the opposing sidewalls of the first and second trenches includes forming an insulating material selected from the group of insulating material comprising aluminum nitride and silicon nitride.

3. The method of claim 2, wherein forming the trench fill material in the first and second trenches includes forming an electrically conductive material in the first and second trenches, wherein the electrically conductive material contacts the floor of the first trench of the plurality of trenches or the floor of the second trench of the plurality of trenches from which the insulating material is absent.

4. The method of claim 3, wherein forming the trench fill material in the first and second trenches includes forming doped polysilicon in the first and second trenches, wherein the doped polysilicon contacts the body of semiconductor material through the floor of the first trench of the plurality of trenches or the floor of the second trench of the plurality of trenches from which the insulating material is absent.

5. The method of claim 2, wherein forming the trench fill material in the first and second trenches includes forming an electrically insulating material in the first and second trenches.

6. The method of claim 1, further including forming the layer of insulating material on the floor of the first trench of the plurality of trenches or the floor of the second trench of the plurality of trenches, wherein insulating material is absent from the other of the floor of the first trench of the plurality of trenches or the second trench of the plurality of trenches floors of the first and second trenches.

7. The method of claim 6, wherein forming the layer of insulating material on the floors and on the opposing sidewalls of the first and second trenches includes forming an insulating material selected from the group of insulating material comprising aluminum nitride and silicon nitride.

8. The method of claim 6, wherein forming the trench fill material in the first and second trenches includes forming an electrically conductive material in the first and second trenches, wherein the electrically conductive material contacts the floor of the first trench of the plurality of trenches or the floor of the second trench of the plurality of trenches from which the insulating material is absent.

9. The method of claim 1, wherein providing the body of semiconductor material having a surface includes providing the body of semiconductor material selected from the group of semiconductor materials comprising silicon, silicon nitride, gallium nitride, and sapphire.

10. The method of claim 1, further including:
forming a buffer layer over the layer of III-nitride material;
forming a channel layer over the buffer layer;
forming a strained layer over the buffer layer; and
forming a control electrode and first and second current carrying electrodes over the strained layer.

11. A method for manufacturing a semiconductor component, comprising:
providing a body of semiconductor material;
forming a plurality of layers of compound semiconductor material on the body of semiconductor material;
forming a first trench through the plurality of layers of compound semiconductor material, the first trench having first and second sidewalls and a floor;
forming a second trench through the plurality of layers of compound semiconductor material, the second trench having first and second sidewalls and a floor;
forming an insulating material on the first and second sidewalls of the first trench, and on the first and second sidewalls of the second trench, and on one of the floor of the first trench of the plurality of trenches or the floor of the second trench of the plurality of trenches, wherein insulating material is absent from the other of the floor of the first trench of the plurality of trenches or the floor of the second trench of the plurality of trenches;
forming a trench fill material in the first and second trenches; and
forming a control electrode and first and second current carrying electrodes over the plurality of layers of compound semiconductor material that are between the first and second trenches.

12. The method of claim 11, wherein forming the plurality of layer of compound semiconductor material includes:
forming a layer of aluminum nitride on the body of semiconductor material;
forming a layer of III-N material on the layer of aluminum nitride;
forming a gallium nitride layer on the layer of III-N material; and
forming a layer of aluminum gallium nitride on the gallium nitride layer.

13. The method of claim 12, further including forming the layer of III-N material from gallium nitride.

14. The method of claim 11, wherein forming the trench fill material in the first and second trenches includes forming one of doped polysilicon or oxide in the first and second trenches.

15. The method of claim 11, wherein forming the insulating material on the first and second sidewalls of the first trench and the first and second sidewalls of the second trench further includes forming the insulating material on the floor of the second trench.

16. The method of claim 15, wherein forming trench fill material in the first and second trenches includes forming doped polysilicon in the first and second trenches, wherein the doped polysilicon in one of the first trench or the second trench from which the dielectric material is absent from the floor contacts the body of semiconductor material.

17. The method of claim 16, further including electrically coupling one of the first current carrying electrode or the second current carrying electrode to the trench fill material in the first trench.

18. A semiconductor component, comprising:
a body of semiconductor material;
a plurality of layers of compound semiconductor material over the body of semiconductor material;
first and second filled trenches extending into the plurality of layers of compound semiconductor material, wherein the first trench includes first and second sidewalls and a floor and a first dielectric liner over the first and second sidewalls and wherein the second trench includes first and second sidewalls and a floor and a second dielectric liner over the first and second sidewalls of the second trench; and
a source electrode, a drain electrode, and a gate electrode over the plurality of layers of compound semiconductor material.

19. The semiconductor component of claim 18, wherein the second dielectric liner is over the floor of the second trench and wherein the trench fill material comprises polysilicon, wherein the polysilicon contacts the body of semiconductor material.

20. The semiconductor component of claim 19, further including an electrical interconnect that connects one of the source electrode or the drain electrode to the trench fill material in the first trench.
